(19) United States
(12) Patent Application Publication
(10) Pub. No.: US 2026/0092373 A1
(43) Pub. Date: Apr. 2, 2026

(54) REFLECTORS, CHAMBER ARRANGEMENTS AND SEMICONDUCTOR PROCESSING SYSTEMS INCLUDING REFLECTORS, AND METHODS OF DEPOSITING MATERIAL LAYERS ONTO SUBSTRATES USING CHAMBER ARRANGEMENTS AND SEMICONDUCTOR PROCESSING SYSTEMS HAVING REFLECTORS

(71) Applicant: ASM IP Holding B.V., Almere (NL)

(72) Inventors: Jing Yuan, Phoenix, AZ (US); Kishor Patil, Chandler, AZ (US); Wentao Wang, Chandler, AZ (US); Krishnaswamy Mahadevan, Tempe, AZ (US); Fan Gao, Chandler, AZ (US); Junwei Su, Chandler, AZ (US); Haotian Wan, Scottsdale, AZ (US); Ivan Hernandez del Castillo, Gilbert, AZ (US)

(21) Appl. No.: 19/341,198

(22) Filed: Sep. 26, 2025

Related U.S. Application Data
(60) Provisional application No. 63/701,893, filed on Oct. 1, 2024.

(51) Int. Cl. C23C 16/48; C23C 16/52

(52) U.S. Cl. CPC C23C 16/482; C23C 16/52

(57) ABSTRACT

A reflector includes a body with a first surface having a first aperture and a second surface with a reflective material and a second aperture, separated by the body's thickness. The apertures are fluidly coupled by a channel extending through the body, with one aperture positioned closer to the side than the other. The channel is angled to issue coolant from the second aperture at an oblique flow angle relative to the reflector body. Chamber arrangements, semiconductor processing systems, and material layer deposition methods using the reflector are also described.

### CROSS-REFERENCE TO RELATED APPLICATIONS

This application is a nonprovisional of, and claims priority to and the benefit of, U.S. Provisional Ser. No. 63/701,893 , filed Oct. 1, 2024 and entitled “REFLECTORS, CHAMBER ARRANGEMENTS AND SEMICONDUCTOR PROCESSING SYSTEMS INCLUDING REFLECTORS, AND METHODS OF DEPOSITING MATERIAL LAYERS ONTO SUBSTRATES USING CHAMBER ARRANGEMENTS AND SEMICONDUCTOR PROCESSING SYSTEMS HAVING REFLECTORS,” which is hereby incorporated by reference herein.

### FIELD OF DISCLOSURE

The present disclosure generally relates to depositing material layers onto substrates, and more particularly to controlling temperature within semiconductor processing systems during the deposition of material layers onto substrates.

### BACKGROUND OF THE DISCLOSURE

Films are commonly deposited onto substrates, such as during the fabrication of semiconductor devices. Film deposition is generally accomplished by supporting a substrate within a reaction chamber, heating the substrate to a desired deposition temperature, and contacting the substrate with a material layer precursor under environmental conditions (e.g., temperature and pressure) selected to cause a film to deposit onto the substrate. Once the film develops a desired property (e.g., thickness) the substrate is typically removed from the reaction chamber and sent on for further processing, as appropriate for the device being fabricated using the film.

In some deposition operations a reflector may be employed to heat the substrate, such as in cooperation with a heat source included in the reaction chamber. The reflector may be supported outside of the reaction chamber. The reflector may further cooperate with a coolant source to control temperature of the reaction chamber during deposition of the film onto the substrate.

Such systems and methods have generally been considered suitable for their intended purpose. However, there remains a need in the art for improved reflectors, reaction chambers and semiconductor processing systems including reflectors, and methods of depositing material layers onto substrates using reaction chambers and semiconductor processing systems including reflectors. The present disclosure provides a solution to this need.

### SUMMARY

The following summary presents a simplified summary of certain features. The summary is not an extensive overview and is not intended to identify key or critical elements.

In accordance with various embodiments of the disclosure, a reflector is provided including a reflector body having a first surface bounded in part by a side of the reflector body and defining therein a first surface aperture; and a second surface also bounded in part by the side of the reflector body and including a reflective material, the second surface separated from the first surface by a thickness of the reflector body, the second surface defining therein a second surface aperture, is provided, the method comprising the second surface aperture fluidly coupled to the first surface aperture by a channel extending through the thickness of the reflector body, one of the first surface aperture and the second surface aperture is disposed closer to the side of the reflector than the other of the first surface aperture and the second surface aperture, and at least a portion of the channel is angled relative to at least one of the first surface and the second surface to issue a coolant from the second surface aperture at a flow angle oblique relative to the reflector body.

In some embodiments, the first surface of the reflector body defines a plurality of expansion grooves extending towards the second surface and partially through the thickness of the reflector body.

In some embodiments, the reflector body is formed from a copper-containing material and the reflective material includes gold.

In some embodiments, the reflector body defines a port extending through the thickness of the reflector body, the port optically coupling the second surface of the reflector body along an optical axis substantially parallel to the side of the reflector body, with the channel oblique relative to the optical axis.

In some embodiments, the reflector body includes a first longitudinal side and a second longitudinal side disposed substantially orthogonal to the side, and the first surface aperture and second aperture extend in a direction between the first longitudinal side and second longitudinal side, the first surface aperture and the second surface aperture thereby cooperating with the channel to define an angled slot extending through the reflector body.

In some embodiments, the first surface aperture is larger than the second surface aperture.

In some embodiments, the channel narrows between the first surface aperture and the second surface aperture.

In some embodiments, a portion of the channel extends through a thickness of the reflector body at an angle relative to a surface normal.

In some embodiments, the angle is about 5° relative to the surface normal.

In some embodiments, a second portion of the channel narrows toward a center of the channel as it extends through the thickness of the reflector body.

In some embodiments, the first surface aperture and the second surface aperture define a slot within the reflector body, the slot having a major dimension and a minor dimension, the major dimension substantially parallel to the side of the reflector body.

In some embodiments, the reflector body is further configured to overlap a ribbed exterior surface of a wall of a chamber body of a semiconductor processing system, with the channel configured to direct the coolant into a gap defined between adjacent ribs on the ribbed exterior surface of the wall of the chamber body.

In some embodiments, at least one slot extending through the reflector body is configured to receive a removable quartz rod, the quartz rod operable to block airflow through the at least one slot.

In some embodiments, the number and arrangement of quartz rods inserted into the slots is adjustable to tune the temperature within a chamber during a deposition process.

In some embodiments, the reflector body is formed as a single piece with only the necessary slots for process control, and unused slots are omitted.

In some embodiments, the method further includes one or more pyrometer ports extending through the reflector body, each one of the one or more pyrometer ports configured to optically couple a pyrometer to a chamber for temperature monitoring.

In accordance with various embodiments of the disclosure, a chamber arrangement is provided including a reflector as disclosed, the chamber arrangement including: a chamber body spaced apart from the reflector, a substrate support arranged within an interior of the chamber body and supported for rotation about a rotation axis, and a heater element array arranged between the chamber body and the reflector, wherein the channel is oblique relative to a substrate seating plane defined by the substrate support, is provided, the method comprising.

In some embodiments, the reflector includes one or more removable quartz rods inserted into selected slots to control airflow and chamber body temperature.

In some embodiments, the chamber body temperature is maintained within a range of about 550° C. to about 600° C. during operation.

In some embodiments, the chamber body extends between an injection end and a longitudinally opposite exhaust end, with the chamber body having a plurality of ribs extending laterally about the chamber body and longitudinally spaced apart between the injection end and the exhaust end, and the channel oblique relative to the plurality of ribs.

In some embodiments, the substrate support comprises a susceptor structure configured to receive a semiconductor substrate, and the heater element array is configured to direct electromagnetic radiation toward the chamber body.

In some embodiments, the reflector is configured to reduce or eliminate chamber coating during high-temperature deposition processes.

In some embodiments, the reflector includes one or more removable quartz rods inserted into selected slots to control airflow and chamber body temperature.

In some embodiments, the chamber body temperature is maintained within a range of about 550° C. to about 600° C. during operation.

In accordance with various embodiments of the disclosure, a semiconductor processing system is provided including a reflector as disclosed, the semiconductor processing system including a chamber arrangement. In some embodiments, the semiconductor processing system includes a chamber body spaced apart from the reflector, a heater element array supported between the second surface of the reflector body and the chamber body, and a substrate support arranged within an interior of the chamber body and supported therein for rotation about a rotation axis.

In some embodiments, the semiconductor processing system further includes one or more heater elements disposed between the chamber body and the reflector.

In accordance with various embodiments of the disclosure, a material layer deposition method is provided including, at a chamber arrangement including a chamber body and a reflector spaced apart from the chamber body; the reflector including a reflector body having a first surface bounded in part by a side of the reflector body and defining therein a first surface aperture; a second surface also bounded in part by the side of the reflector body and including a reflective material, the second surface separated from the first surface by a thickness of the reflector body, the second surface defining there a second surface aperture, the second surface aperture fluidly coupled to the first surface aperture by a channel extending through the thickness of the reflector body, one of the first surface aperture and the second surface aperture is disposed closer to the side of the reflector than the other of the first surface aperture and the second surface aperture, and the channel angled relative to at least one of the first surface and the second surface, is provided, the method comprising seating a substrate within the chamber body; heating the substrate using a heater element array disposed between the reflector and the chamber body at least in part using electromagnetic radiation emitted by the heater element array in a direction substantially opposite the substrate and reflected by the second surface of the reflector body; contacting the substrate with a material layer precursor such that a material layer deposits onto the substrate; and issuing a coolant from the second surface aperture at a flow angle oblique relative to the reflector body, whereby the chamber body is locally cooled during deposition of the material layer onto the substrate by the coolant issued from the second surface aperture.

In some embodiments, the method further includes adjusting the number and arrangement of quartz rods inserted into slots of the reflector to tune the chamber body temperature during deposition processes.

In some embodiments, the chamber body temperature is maintained within a range of about 550° C. to about 600° C. and chamber coating is reduced or eliminated.

In some embodiments, the method further includes issuing the coolant further includes causing cooling of a portion of an interior of the chamber body during deposition of the material layer onto the substrate.

In accordance with various embodiments of the disclosure, a reflector for a semiconductor processing chamber is provided including a reflector body having a plurality of slots extending through a thickness of the reflector body; a plurality of quartz rods removably inserted into selected slots, each of the plurality of quartz rods configured to block airflow through the corresponding slot; wherein the number and arrangement of quartz rods is adjustable to tune the temperature within the semiconductor processing chamber during a deposition process.

In some embodiments, the reflector body is formed as a single piece with only the necessary slots for process control, and unused slots are omitted.

In some embodiments, the reflector further includes one or more pyrometer ports extending through the reflector body, each of the one or more pyrometer ports configured to optically couple a pyrometer to the semiconductor processing chamber for temperature monitoring. In some embodiments, the semiconductor processing chamber temperature is maintained within a range of about 550° C. to 600° C. during operation.

In addition to one or more of the features described above, or as an alternative, further examples of the method may include that issuing the coolant further includes causing cooling of a portion of an interior of the chamber body during deposition of the material layer onto the substrate.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWINGS

Some features are shown by way of example, and not by limitation, in the accompanying drawings. In the drawings, like numerals reference similar elements.

FIG. 1 depicts a partial schematic view of an example semiconductor processing system.

FIG. 2 depicts an example cooling kit of the semiconductor processing system.

FIG. 3 depicts an example chamber arrangement and a portion of the cooling kit.

FIG. 4 depicts a first alternate view of a portion of the semiconductor processing system of FIG. 1.

FIG. 5 depicts a second alternate view of a portion of the semiconductor processing system of FIG. 1.

FIG. 6A depicts an example top reflector.

FIG. 6B depicts the reflective surface side of the example top reflector of FIG. 6A.

FIG. 7 depicts a cross-sectional view of the example top reflector of FIGS. 6A and 6B.

FIG. 8 depicts an example top reflector disposed above a heater array and top wall of a chamber body.

FIG. 9 depicts an alternative example top reflector.

FIG. 10 depicts an alternative example top reflector.

FIG. 11 shows an example method associated with reflectors herein.

### DETAILED DESCRIPTION

The accompanying drawings, which form a part hereof, show examples of the disclosure. It is to be understood that the examples shown in the drawings and/or discussed herein are non-exclusive and that there are other examples of how the disclosure may be practiced.

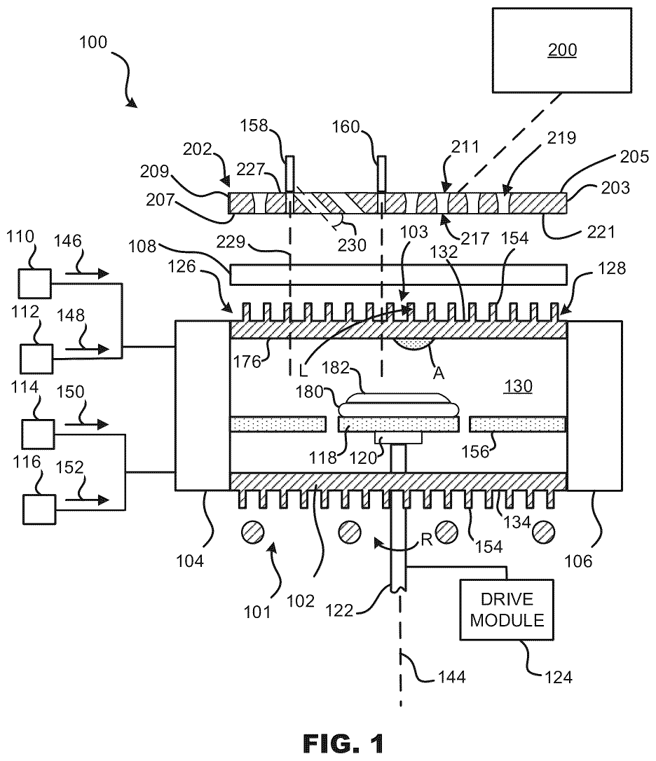

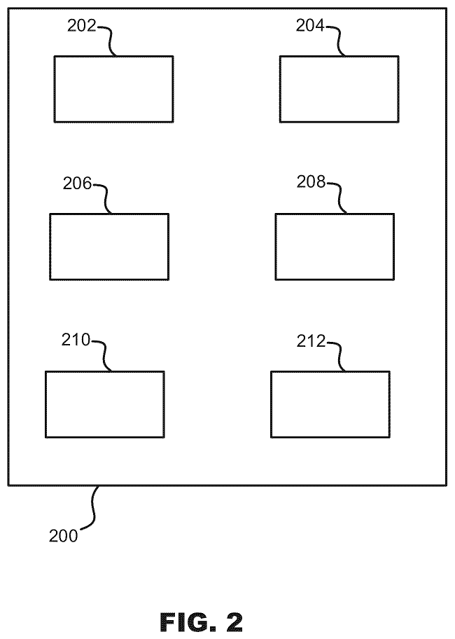

Reference will now be made to the drawings wherein like reference numerals identify similar structural features or aspects of the subject disclosure. FIG. 1 depicts a partial schematic view of an example semiconductor processing system 100 including a reflector 202 in accordance with the present disclosure. Other examples of reflectors, chamber arrangements and semiconductor processing systems including reflectors, and material layer deposition methods as well as related cooling kits, or aspects thereof, are provided in FIGS. 2-11, as will be described. The systems and methods described herein may be used to control temperature of chamber bodies included in chamber arrangements of semiconductor processing systems, such as during the deposition of silicon-containing material layers epitaxial with an underlying substrate using chemical vapor deposition (CVD) techniques during the fabrication of semiconductor devices. However, it is to be understood and appreciated that the present disclosure is not limited to any particular type of material layer or deposition technique, nor to material layer deposition in general.

Referring to FIG. 1, the semiconductor processing system 100 may include a chamber arrangement 101 including a chamber body 102, an injection flange 104, an exhaust manifold 106, and a heater element 108. The semiconductor processing system 100 may also or alternatively include a first precursor source 110, one or more second precursor source(s) 112, a purge/carrier gas source 114, and a halide source 116. Additionally or alternatively, the semiconductor processing system 100 may further include a substrate support 118, a support member 120, a shaft 122, and a drive module 124. Although a particular example arrangement of the chamber arrangement 101 is shown and described (e.g., a cold wall crossflow-type chamber arrangement), it is to be understood and appreciated that semiconductor processing systems having other types of chamber arrangements may also benefit from the present disclosure.

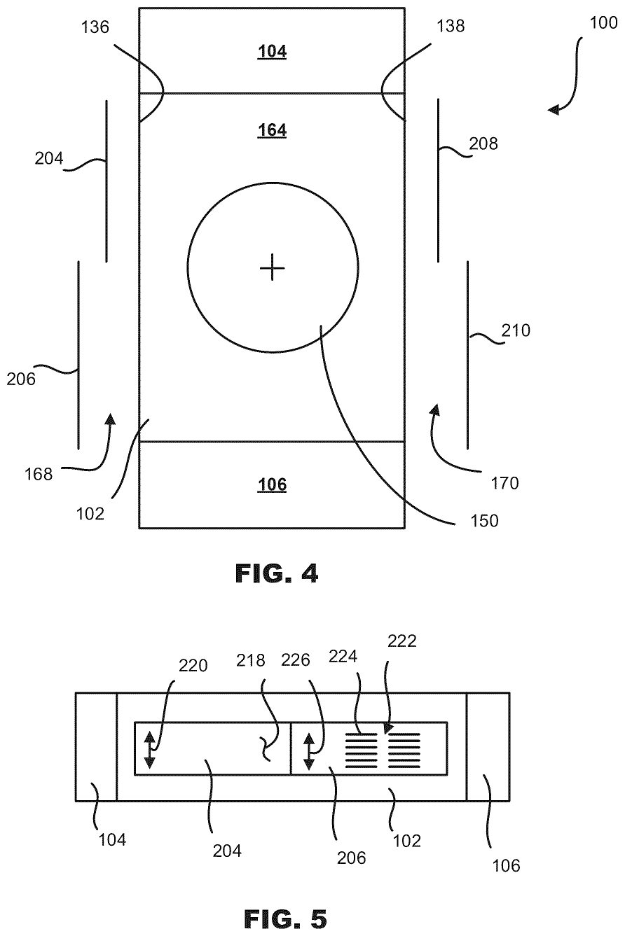

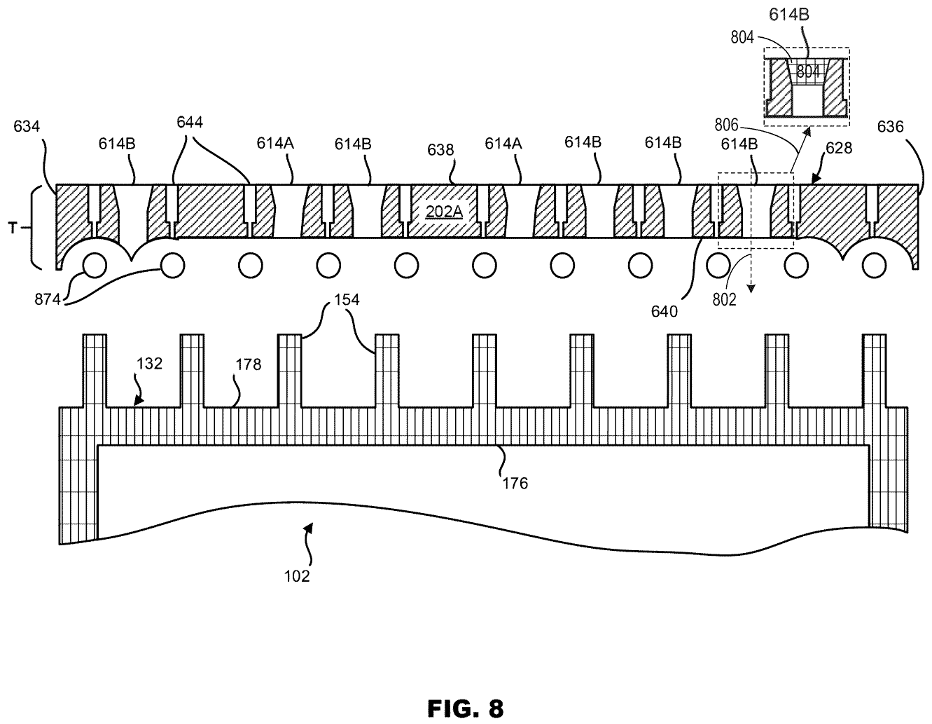

The chamber body 102 may have an injection end 126 and a longitudinally opposite exhaust end 128, substantially opposed to the injection end 126, and an interior 130. The interior 130 of the chamber body 102 may be bounded by a top wall 132, extending between the injection end 126 and the exhaust end 128 of the chamber body 102, a bottom wall 134 below the top wall 132 and extending between the injection end 126 and the exhaust end 128 of the chamber body 102, a first side wall (e.g., side wall 136 shown in FIG. 4) extending between and/or coupling lateral edges of the top wall 132 and the bottom wall 134 to one another, and a laterally opposite second side wall (e.g., side wall 138 shown in FIG. 4) extending between and/or coupling opposite lateral edges of the top wall 132 and the bottom wall 134 to one another. In example configurations and as depicted in FIG. 1, the top wall 132 and/or the bottom wall 134 may be ribbed. For example, referring to FIG. 1, the top wall 132 and/or the bottom wall 134 may comprise a plurality of ribs 154 extending from an external surface thereof and laterally about the chamber body 102, the plurality of ribs 154 longitudinally spaced apart from one another between the injection end 126 and exhaust end 128 of the chamber body 102, laterally adjacent ribs defining a gap 103 therebetween. In certain example configurations, the chamber body 102, or a portion thereof, may be formed from a substantially transparent material, for example a material transparent to electromagnetic radiation within an infrared waveband, such as a ceramic material like fused silica or quartz. The substantially transparent material may be transmissive to electromagnetic radiation, for example, emitted by the heater element 108. A substrate 180 (e.g., wafer) may be disposed and/or supported within the chamber body 102. The substrate 180 may be heated, for example, using the heater element 108, and/or a heater element array (e.g., heater element array 874 shown in FIG. 8). In accordance with certain example configurations, at least a portion of the chamber body 102 may be formed from quartz. As described, the top wall 132 and/or the bottom wall 134 of the chamber body 102 may comprise ribs 154. The ribs 154 may extend outward from one or more of the top wall 132 and the bottom wall 134. The ribs 154 may provide structural support to the chamber body 102 and/or allow the interior 130 of the chamber body 102 to be maintained at relatively low pressure relative to the environment outside of the chamber body 102. In alternative example configurations, the ribs 154 of one or more of the top wall 132 and the bottom wall 134 may be omitted.

As used herein the term “substrate” may refer to any underlying material or materials, including any underlying material or materials that may be modified, or upon which, a device, a circuit, or a material layer (e.g., a film) may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

The substrate support 118 may be arranged within the interior 130 of the chamber body 102 and supported therein for rotation R about a rotation axis 144, and may include a susceptor structure. The substrate support 118 may be supported by the support member 120. The substrate support 118 may be arranged along and/or may comprise a rotation axis 144 relative to the support member 120. The substrate support 118 may be disposed in fixed rotation relative to the support member 120. The support member 120 may be in fixed rotation relative to the shaft 122. The shaft 122 may be supported for rotation R about the rotation axis 144. The shaft 122 may extend through the bottom wall 134 of the chamber body 102 and may couple the substrate support 118 and the support member 120 to drive module 124. The drive module 124 may be operably connected to the substrate support 118, for example, via the shaft 122 and the support member 120. The drive module 124 may be configured to rotate the substrate support 118 via the shaft 122 and the support member 120 about the rotation axis 144, for example, during the deposition of a material layer 182 onto the substrate 180. The substrate 180 may comprise a wafer, such as a semiconductor wafer. The material layer 182 may comprise an epitaxial material layer, such as a silicon-containing and/or a germanium-containing material layer. It is also contemplated that, in accordance with certain example configurations, the material layer 182 may be a thick epitaxial material layer formed, for example, during the fabrication of a power electronics device. An example power device may include an insulated gate bipolar transistor semiconductor device. A “thick” layer may comprise a layer having a thickness that is greater than 25 microns, greater than 50 microns, greater than 75 microns, greater than 100 microns, or that is between about 25 microns and about 100 microns.

The exhaust manifold 106 may be connected to the exhaust end 128 of the chamber body 102. The exhaust manifold 106 may be configured to couple the chamber body 102 to an exhaust source, such as a scrubber. In certain example configurations, the chamber body 102 may comprise an exhaust flange extending outward from and about the walls of the chamber body 102. The exhaust manifold 106 may be connected to the exhaust flange. The injection flange 104 may be connected to the injection end 126 of the chamber body 102. The injection flange may couple the first precursor source 110, one or more second precursor source 112, the purge/carrier gas source 114, and/or the halide source 116 to the chamber body 102. In certain example configurations, the chamber body 102 may comprise an injection flange extending outward from and about the injection end 126 of the chamber body 102. One or more of the chamber body 102, the injection flange 104, and the exhaust manifold 106 may be substantially as shown and described in U.S. Patent Application Pub. No. 2010/0116207 A1, filed on Nov. 5, 2009 and titled “Reaction Chamber”, the contents of which are incorporated herein by reference in their entirety.

The first precursor source 110 may be fluidly coupled to the chamber body 102 via the injection flange 104. The first precursor source 110 may be further configured to provide a first precursor 146 to the chamber body 102 (e.g., to the interior 130 of the chamber body 102). In certain example configurations, the first precursor 146 may include a silicon-containing precursor. Examples of silicon-containing precursors may include, by way of non-limiting examples, silane (SiH₄), dichlorosilane (H₂SiCl₂), trichlorosilane (HCl₃Si), and higher order silane compounds, such as tetramethylsilane (Si(CH₃)₄).

The one or more second precursor source 112 may be fluidly coupled to the chamber body 102 by the injection flange 104. The one or more second precursor source 112 may be configured to provide one or more second precursor 148 to the chamber body 102 (e.g., to the interior 130 of the chamber body 102). In certain example configurations, the one or more second precursor 148 may include a dopant, such as an n-type and/or a p-type dopant-containing precursor. The one or more second precursor 148 may include, for example, a germanium precursor. Examples of germanium precursors may include, by way of non-limiting examples, germane (GeH₄), germanium tetrafluoride (GeF₄), and tributylgermanium hydride ([CH₃(CH₂)₃]₃GeH).

The purge/carrier gas source 114 may be fluidly coupled to the chamber body 102 by the injection flange 104. The purge/carrier gas source 114 may be configured to provide a purge/carrier gas 150 to the chamber body 102 (e.g., to the interior 130 of the chamber body 102). In certain examples, the purge/carrier gas 150 may include hydrogen (H₂), helium (He), nitrogen (N₂), argon (Ar), and/or krypton (Kr), or a mixture thereof.

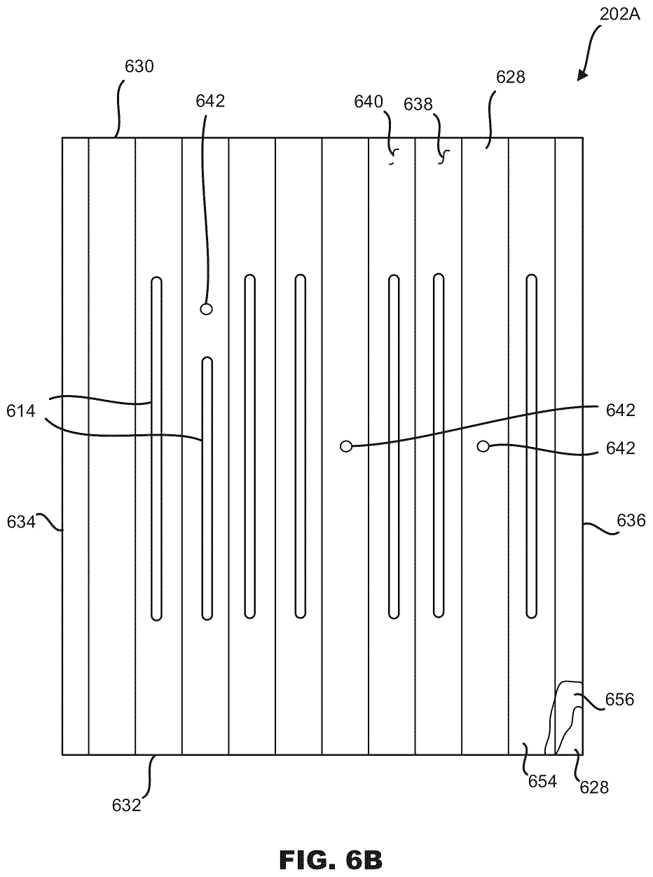

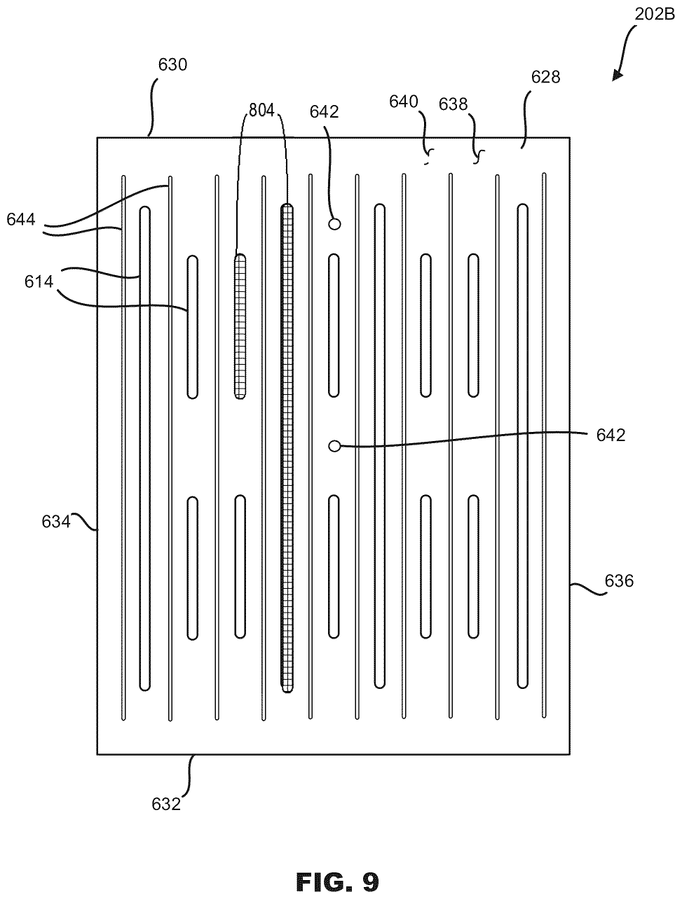

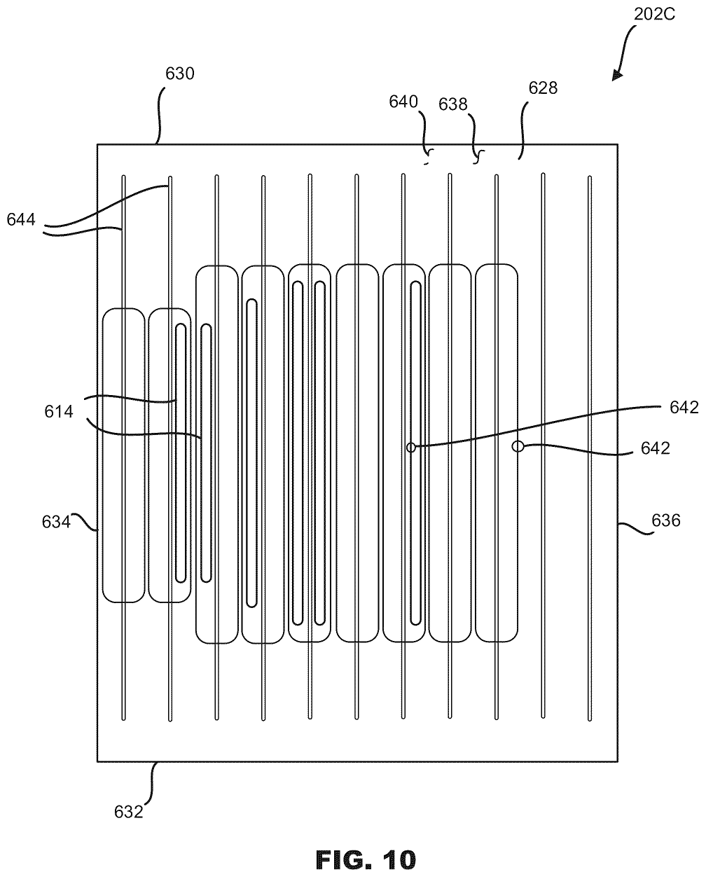

The halide source 116 may be fluidly coupled to the interior 130 of the chamber body 102 by the injection flange 104. The halide source 116 may be configured to provide a halide 152 to the chamber body 102 (e.g., an interior 130 of the chamber body 102). In certain examples, the halide 152 may include chlorine. For example, the halide 152 may include hydrochloric acid (HCl) or chlorine (Cl₂). Deposition of the material layer 182 onto the substrate 180 may be facilitated and/or aided by supporting the substrate 180 within the chamber body 102 on the substrate support 118, heating the substrate 180 to a predetermined material layer deposition temperature, rotating the substrate 180 using the substrate support 118 about the rotation axis 144, and flowing the first precursor 146 and/or the second precursor 148 across the substrate 180. As the first precursor 146 and/or the second precursor 148 flow across the substrate 180, the material layer 182 may deposit onto the substrate 180. The material layer 182 may deposit on the substrate 180 in accordance with a temperature of the substrate 180. Heating of the substrate 180 may be accomplished via a heating element (e.g., heater element 108) or heating element array. The heating element and/or heating element array may be positioned outside of the chamber body 102 (e.g., the heater element 108 or a heater element array 874 shown in FIG. 8). The heater element 108 or the heater element array may be arranged above the top wall 132 of the chamber body 102. Additionally or alternative, the heater element 108 and/or the heater element array may be radiantly coupled to the substrate support 118 (and the substrate 180) via the walls (e.g., top wall 132 and/or bottom wall 134) of the chamber body 102. A top reflector 202 (e.g., a portion of cooling kit 200) (e.g., top reflector 202A of FIGS. 6A-8, top reflector 202B of FIG. 9 and/or top reflector 202C of FIG. 10) may be disposed above the heater element 108. The top reflector 202 may be configured to cooperate with the heater element 108, for example, to reflect electromagnetic radiation emitted from the heater element 108 in a direction substantially opposite the chamber body 102, toward the chamber body 102, for example, to radiantly heat the substrate support 118 and/or the substrate 180. An example configuration of the chamber body 102 may be arranged substantially as shown and described in U.S. Application Publication No. 2018/0363139 A1, filed Apr. 25, 2018 and titled “Semiconductor Processing Apparatus and Methods for Calibrating a Semiconductor Processing Apparatus”, the contents of which are incorporated herein by reference in their entirety.

The semiconductor processing system 100 may further comprise first pyrometer 158. Additionally or alternatively, the system 100 may further comprise one or more second pyrometers 160. The pyrometer 158 and one or more second pyrometers 160 may be coupled (e.g., optically) to the chamber body 102 by the top reflector 202. Additionally or alternatively, the pyrometers 158 and 160 may be configured to record and/or report the temperature of one or more of the chamber body 102, the substrate support 118, and/or the substrate 180.

It may be appreciated in view of the present disclosure that differences in temperature across portions of the chamber body 102 and/or the substrate 180 may cause and/or result in a difference in deposition rate of material layer 182 and/or an amount of material layer 182 deposited. Accordingly, it may be desirable to increase the evenness of the temperature across one or more portions of the chamber body 102 and/or the substrate 180 during deposition. To improve the evenness of cooling across portions of the chamber body 102 and/or the substrate 180, for example to direct coolant toward a chamber location L otherwise prone to be higher in temperature than the remainder of the chamber body 102 and thereby apt to promote development of an interior surface accretion A, the reflector 202 is provided.

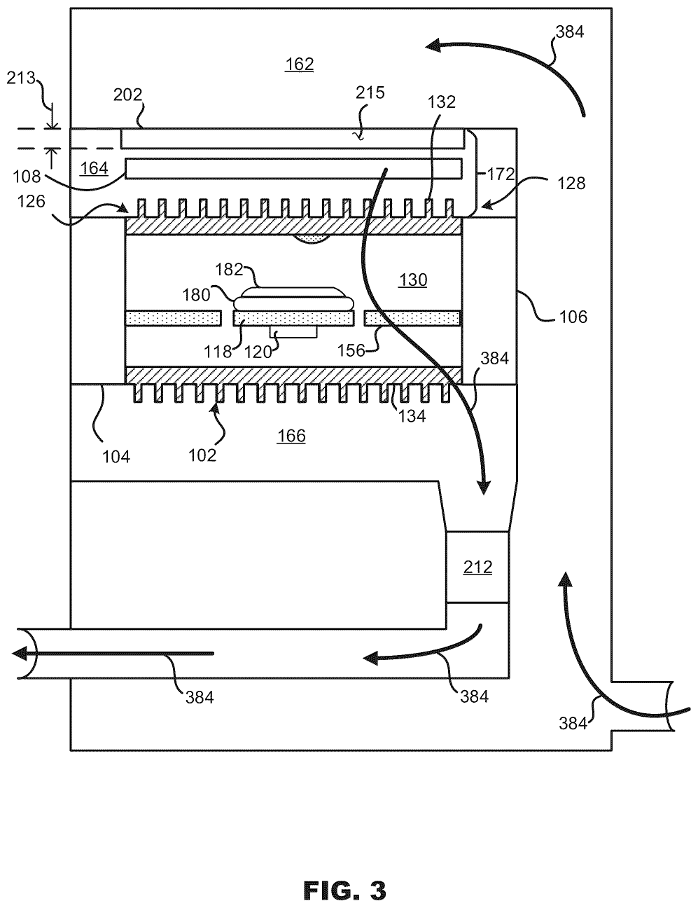

In the illustrated example the reflector 202 includes a reflector body 203 having a first surface 205 and a second surface 207. The first surface 205 is bounded in part by a side 209 of the reflector body 203 and defines therein a first surface aperture 211. The second surface 207 is similar to the first surface 205 and is also bounded by the side 209 of the reflector body 203. The second surface 207 is additionally separated from the first surface 205 by a thickness 213 (shown in FIG. 3) of the reflector body 203, includes a reflective material 215 (shown in FIG. 3), and defines therein a second surface aperture 217 fluidly coupled to the first surface aperture 211 by a channel 219 extending through the thickness 213 of the reflector body 203. It is contemplated that of the first surface aperture 211 and the second surface aperture 217 be disposed closer to the side 209 of the reflector body 203 bounding both the first surface 205 and the second surface 207 of the reflector body 203 than the other of the first surface aperture 211 and the second surface aperture 217, the channel 219 thereby configured to issue a coolant 384 (shown in FIG. 3) from the second surface aperture 217 at a flow angle 230 oblique relative to the reflector body 203.

In certain examples the flow angle 230 may be such that the channel 219 is oblique relative to one or more of the ribs 154 of the chamber body 102, for example such that the coolant 384 issued from the second surface aperture 217 is directed toward a gap 103 defined between two longitudinally adjacent ribs 154. In this respect the flow angle defined by the channel 219 may be between about 5° and about 85°, or between about 5° and about 45°, or even between about 5° and about 25°. Advantageously, angles within these ranges enable directing coolant into gaps in chamber bodies having irregularly spaced ribs and laterally extending heater elements arranged on a substantially uniform longitudinal pitch. In accordance with certain examples, the first surface aperture 211 and the second surface aperture 217 may have a major dimension 223 (shown in FIG. 6A) and a minor dimension 225 (shown in FIG. 6A). The major dimension 223 may be substantially parallel to the side 209 of the reflector body 203, the first surface aperture 211 and the second surface aperture 217 cooperating with the channel 219 to define a slot, and more specifically an angle slot, extending through the reflector body 203 to direct the coolant 304 into the gap 103 between the longitudinally adjacent ribs 154.

In the illustrated example the reflector body 203 is formed from a copper-containing material 221, such brass or bronze by way of non-limiting examples. In such examples the reflective material 215 may include a layer of gold deposited onto the reflector body 203, for example directly onto the copper-containing material 221 or onto an intermediate material, which may include silver and/or nickel. It is contemplated that the reflector body 203 may be generally planar in contour. It is also contemplated that the reflector body 203 may be rectangular in shape.

In the illustrated example the reflector body 203 further defines a port 227 therethrough. It is contemplated that the port 227 extend through the thickness 213 of the reflector body 203, the port 227 thereby optically coupling the second surface 207 of the reflector body 203 to the first surface 205 of the reflector body 203. It is also contemplated that the port 227 may define an optical axis 229 therethrough. The optical axis 229 may be substantially parallel to the side 209 of the reflector body 203 and/or substantially orthogonal to the heater element 108 as well as an upper wall of the chamber body 102. The pyrometer 158 may registered to the port 227 such that the pyrometer 158 is optically coupled to the chamber body 102 and/or the interior 130 of the chamber body 102 by the reflector 202 along the optical axis 229. The channel 219 may be oblique relative to the optical axis 229.

FIG. 2 depicts an example cooling kit 200 including the reflector 202 for use in the semiconductor processing system 100, for example to upgrade the semiconductor processing system 100 for improved cooling. With reference to FIG. 2, the cooling kit 200 may be configured and/or arranged to substantially maintain and/or affect temperatures on a surface (e.g., an interior surface) of a top wall (e.g., top wall 132 of FIG. 1) of the chamber body 102. Additionally or alternatively, the cooling kit may be configured and/or arranged to maintain and/or affect temperatures in an interior of a chamber body (e.g., the interior 130 of the chamber body 102). The temperatures may be less than about 1250 degrees Celsius, less than about 800 degrees Celsius, less than about 750 degrees Celsius, less than about 700 degrees Celsius, less than about 750 degrees Celsius, or less than about 600 degrees Celsius, or may be between about 200 degrees Celsius and about 1250 degrees Celsius. The cooling kit 200 may include the top reflector 202, a first injection end side reflector 204, and a first exhaust end side reflector 206. The cooling kit 200 may also include a second injection end side reflector 208, a second exhaust end side reflector 210, and a blower 212. One or more of the reflectors, for example, the top reflector 202, the first injection end side reflector 204, the first exhaust end side reflector 206, the second injection end side reflector 208, and the second exhaust end side reflector 210, may be configured to limit resistance (e.g., static flow drop) to flow of the coolant (e.g., coolant 384 shown in FIG. 3) across the exterior of the chamber body (e.g., chamber body 102 shown in FIG. 1). The blower 212 may be configured to provide a mass flow (e.g., a relatively high mass flow) of the coolant 384 across the exterior of the chamber body 102 and/or across one or more the reflectors (e.g., the top reflector 202, the first injection end side reflector 204, the first exhaust end side reflector 206, the second injection end side reflector 208, and the second exhaust end side reflector 210). The top reflector 202 may be further configured to direct coolant towards and/or distribute coolant across the top wall (e.g., top wall 132 shown in FIG. 1) of the chamber body 102. The top reflector 202 may be configured to direct coolant towards and/or distribute coolant across the top wall 132, for example, to affect variation of temperature across an interior surface (e.g., interior surface 176 shown in FIG. 1) of the top wall 132 of the chamber body 102, for example, during deposition of the material layer (e.g., material layer 182 shown in FIG. 1) onto the substrate (e.g., substrate 180 shown in FIG. 1).

FIG. 3 depicts an example chamber body 102 and a portion of the cooling kit 200. As described, the substrate support 118 may be disposed within the interior 130 of the chamber body 102 and may be arranged to support the substrate 180, for example, during the deposition of the material layer 182 onto the substrate 180. The heater element 108 or heater element array (e.g., element array 874 shown in FIG. 8) may be disposed and supported above the chamber body 102. The top reflector 202 may be disposed and supported above the heater element 108. The top reflector 202 may be spaced apart from the chamber body 102 by the heater element 108. The blower 212 may be arranged below the chamber body 102. The blower 212 may be in communication (e.g., pneumatic communication) with the chamber body 102, for example, via the top reflector 202. The blower may be in communication with the chamber body 102, for flowing a coolant 384 across a portion of the exterior of the chamber body 102.

The heater element 108 may longitudinally span, at least in part, the chamber body 102. The heater element 108 may extend longitudinally across the top wall 132, for example, between the injection end 126 and the exhaust end 128 of the chamber body 102. Additionally or alternatively, the heater element 108 may extend in the general direction of precursor flow through the chamber body 102 between the injection flange 104 and the exhaust manifold 106, for example, for radiantly communicating heat into the interior 130 of the chamber body 102. The heater element 108 may longitudinally span one or more of the substrate support 118, an outer ring 156 extending about the substrate support 118, and the chamber body 102. The heater element 108 may include a filament. The filament may be disposed within an enclosure (e.g., a cylindrical enclosure). Additionally or alternatively, the heater element 108 may comprise one of an array of heater elements (e.g., cylindrical heater element) laterally spaced from one another over the chamber body 102 and extending longitudinally above the chamber body 102. The heater element 108 or the heater element array (e.g., heater element array 874 shown in FIG. 8) may be substantially as shown and described in U.S. Application Publication No. 2003/0102792 A1, filed on Nov. 5, 2009 and titled “Lamp Design”, the contents of which are incorporated herein by reference in their entirety.

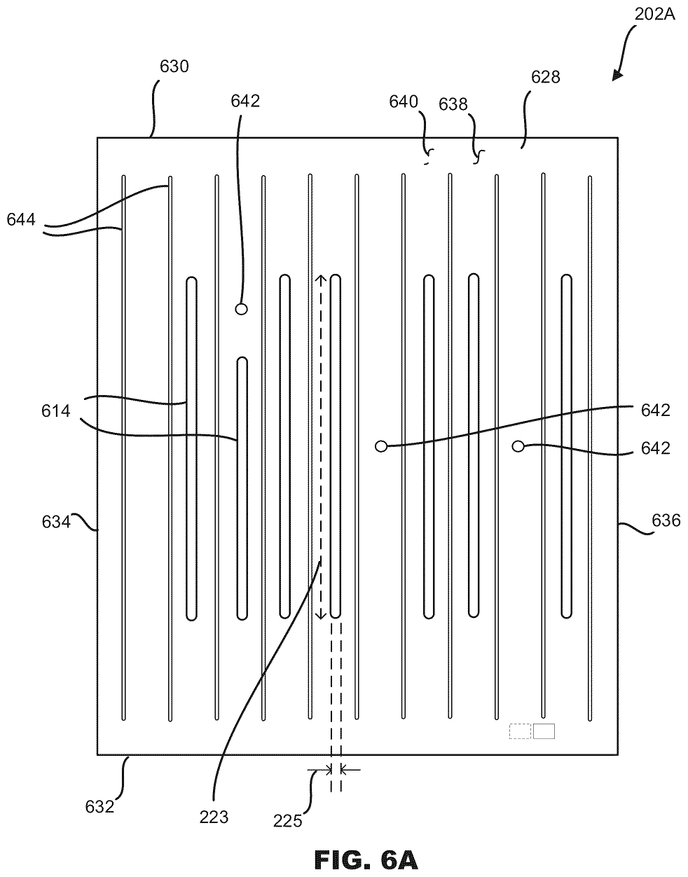

FIG. 4 depicts a first alternate view of a portion of the semiconductor processing system 100 of FIG. 1. And FIG. 5 depicts a second alternate view of a portion of the semiconductor processing system. With reference to FIGS. 4 and 5, the chamber body 102 and a portion of the cooling kit 200 including the side reflectors, for example, the first injection end side reflector 204, the first exhaust end side reflector 206, the second injection end side reflector 208, and the second exhaust end side reflector 210, are shown. The first injection end side reflector 204 and the second injection end side reflector 208 may be arranged on laterally opposite sides of the injection end 126 of the chamber body 102. The first exhaust end side reflector 206 and the second exhaust end side reflector 210 may be arranged on laterally opposite sides of the exhaust end 128 of the chamber body 102 and may be longitudinally offset from the first injection end side reflector 204 and the second injection end side reflector 208 relative to the general direction of precursor flow through the chamber body 102 between the injection flange 104 and the exhaust manifold 106.

Pneumatic communication of the coolant 384 may be accomplished through a plurality of plenums defined between the chamber body 102 and the blower 212. A supply plenum 162 may be disposed and/or defined between the blower 212 and the top reflector 202. A top plenum 164 may be disposed and/or defined between the top reflector 202 and the chamber body 102. A return plenum 166 may be disposed and/or defined between the chamber body 102 and the blower 212. A first lateral plenum 168 may be disposed and defined between the chamber body 102 and the first injection end side reflector 204 and the first exhaust end side reflector 206, and a second lateral plenum 170 is defined between the second injection end side reflector 208 and the second exhaust end side reflector 210. It is contemplated that the supply plenum 162 pneumatically couples the blower 212 to the top reflector 202, that the top reflector 202 pneumatically couples the supply plenum 162 to the top plenum 164, and that the supply plenum 162 pneumatically couples the top reflector 202 to the top wall 132 of the chamber body 102. The first lateral plenum 168 may pneumatically couple the top plenum 164 to the first injection end side reflector 204 and the first exhaust end side reflector 206, the second lateral plenum 170 may pneumatically couple the top plenum 164 to the second injection end side reflector 208 and the second exhaust end side reflector 210, the first injection end side reflector 204 and the first exhaust end side reflector 206 may pneumatically couple the first lateral plenum 168 to the return plenum 166, and that the second injection end side reflector 208 and the second exhaust end side reflector 210 may pneumatically couple the second lateral plenum 170 to the return plenum 166. The return plenum 166 may be pneumatically coupled to the blower 212. Although shown and described herein as a closed loop cooling arrangement, it is to be understood and appreciated that an open loop cooling arrangement may also be employed. For example, the blower 212 may receive makeup air from a source external to the coolant loop.

To cool the chamber body 102, the blower 212 may make up the flow of the coolant 384 provided to the supply plenum 162 using heated coolant received from the return plenum 166 and/or from a makeup duct. From the supply plenum 162, the coolant 384 may flow through the top reflector 202 and onto an exterior surface 178 of the top wall 132 of the chamber body 102 through the top plenum 164. Thereafter, the coolant 384 may flow across an exterior surface 178 into the first lateral plenum 168 and the second lateral plenum 170. As the coolant 384 flows across the exterior surface 178 of the top wall 132 of the chamber body 102, the coolant may remove heat from the top wall 132, cooling the interior surface 176 of the chamber body 102.

From the first lateral plenum 168, a portion of the coolant 384 traverses the first injection end side reflector 204 and the first exhaust end side reflector 206 and flows therefrom into the return plenum 166. From the second lateral plenum 170, another portion of the coolant 384 may traverse the second injection end side reflector 208 and the second exhaust end side reflector 210 and may flow therefrom into the return plenum 166. From the return plenum 166, the coolant 384 may return to the blower 212 for recirculation across the exterior of the chamber body 102. In certain examples, one or more heat exchangers may be arranged along the flow path of the coolant 384, for example within ducting connecting the return plenum 166 and/or the supply plenum 162, as appropriate, to reject (e.g., sink) heat removed from the exterior of the chamber body 102.

As will be appreciated in view of the present disclosure, cooling capability of the semiconductor processing system 100 (shown in FIG. 1) may be determined at least in part by the flow resistance and/or efficiency presented by the reflectors of the cooling kit 200. Additionally, cooling capability may be increased by limiting resistance of flow (e.g., by reducing static pressure drop) and/or variously directing the coolant 384 across the chamber body 102 and/or by increasing mass flow of the coolant 384 across the chamber body 102. The cooling kit 200 may be configured to provide improved cooling capability to the chamber body 102 by (a) limiting resistance to flow of the coolant 384 presented by the reflectors, (b) providing relatively high mass flow rate of the coolant 384 across the exterior of the chamber body 102 using the blower 212, (c) reducing variation in the temperature of the interior surface (e.g., interior surface 176 shown in FIG. 1), and/or (d) configuring the top reflector for improved distribution of coolant 384. In certain example configurations, the top reflector 202 may be separated from the top wall 132 of the chamber body 102 by a spacing distance 172 selected to limit resistance to flow of the coolant 384 between the supply plenum 162 and the top plenum 164. The spacing distance 172 may be less than 100 millimeters, less than 90 millimeters, less than 80 millimeters, or even less than 70 millimeters. The spacing distance 172 may, in certain examples, be selected to cooperate with slots (e.g., the plurality of elongated slots 614 shown in FIGS. 6A and 6B, extending through the top reflector 202 to limit resistance to flow of the coolant 384 through the top reflector 202 and to efficiently distribute coolant across the top wall of the chamber body. In accordance with certain examples, the spacing distance 172 may be between about 50 millimeters and about 150 millimeters, between about 70 and 125 about millimeters, or between about 80 millimeters and about 100 millimeters. It is contemplated that spacing distances within these ranges may limit static pressure drop between the supply plenum 162 and the top plenum 164 to less than about 15 Torr, less than about 10 Torr, less than about 5 Torr, or between about 5 Torr and about 15 Torr. Spacing distances within these ranges may also distribute electromagnetic radiation emitted by the heat lamps across the top wall of the chamber body, limiting the tendency of hot spots to develop on the top wall of the chamber body immediately below individual heat lamps.

The first injection end side reflector 204 and/or the second injection end side reflector 208 may be configured to limit resistance to flow of the coolant between the first lateral plenum 168 and/or the second lateral plenum 170 and the return plenum 166. Either (or both) the first injection end side reflector 204 and the second injection end side reflector 208 may comprise a planar body, for example, a planar body 218. Employment of planar bodies may promote laminar flow of the coolant 384 along the planar body 218, for example, by limiting the tendency of flow to otherwise stagnate along the plate body. Additionally or alternatively, either (or both) of the first injection end side reflector 204 and the second injection end side reflector 208 may comprise a height, for example, a height 220. The height 220 may be smaller than a height of the first side wall 136 of the chamber body 102. Limiting the height of the first injection end side reflector 204 and/or the second injection end side reflector 208 may limit the resistance presented to the coolant 384 as the coolant 384 flows between the first lateral plenum 168 and the return plenum 166.

The first injection end side reflector 204 and/or the second injection end side reflector 208 may comprise louvered portions 222. The louvered portions 222 may include a plurality of louvers 224 thereon, for example, configured to both provide fluid communication between the first lateral plenum 168 and the return plenum 166 and limit reduction in reflectivity of the first injection end side reflector 204. The louvered portions 222 may define therethrough a louver array comprising a plurality of louvers including, for example, 4 louvers, 6 louvers, 8 louvers, or more (e.g., more than 10 louvers), or between 4 louvers and 10 louvers. Each of the louvers 224 may comprise a longitudinal length. The longitudinal length may be greater than 40 millimeters, greater than 60 millimeters, greater than 80 millimeters, greater than 100, or that is between about 40 millimeters and about 100 millimeters. Each of the louvers 224 may comprise a vertical height. The vertical height may be greater than 3 millimeters, greater than 5 millimeters, greater than 7 millimeters, or greater than 9 millimeters, or between about 3 millimeters and about 9 millimeters. The louvers 224 of the louvered portion 222 may reduce resistance to flow of the coolant 384 from the first lateral plenum 168 and/or the second lateral plenum 170 to the return plenum 166 without limiting the reflectivity of the first injection end side reflector 204 and/or the second injection end side reflector 208.

The first exhaust end side reflector 206 and/or the second exhaust end side reflector 210 may comprise a height 226. Height 226 may be smaller than a vertical height of the first side wall 136 of the chamber body 102. The height 226 may be substantially equivalent to the height 220 of the first injection end side reflector 204. As described herein, limiting height of the first injection end side reflector 204 and/or the second injection end side reflector 208 may limit resistance to flow of the coolant 384 from the first lateral plenum 168 and/or the second lateral plenum 170 to the return plenum 166. For example, static pressure drop between the first lateral plenum 168 and/or the second lateral plenum 170 and the return plenum 166 may be less than about 7 Torr, less than about 5 Torr, less than about 3 Torr, or between about 7 Torr and about 3 Torr. Additionally or alternatively, the pressure drop may be about 6 Torr. Pressure drops within these ranges may increase coolant velocity and may improve cooling of the chamber body.

The blower 212 may be configured to increase the mass flow rate of the coolant 384 across the exterior of the chamber body 102. The blower 212 may further be configured to cooperate with slots (e.g., slots 614 of FIGS. 6A-10) extending through the top reflector 202, to distribute and direct the coolant 384 across the exterior surface 178 of the top wall 132 of the chamber body 102. Such distribution and direction of coolant 384 may limit temperature variation on the interior surface 176 of the chamber body 102. For example, the blower 212 may comprise a rating that is greater than about 10 standard cubic feet minute (SCFM), greater than about 40 SCFM, greater than about 60 SCFM, greater than about 100 SCFM, or between about 10 SCFM and about 100 SCFM. With respect to coolant distribution, blowers 212 with ratings within these ranges may cooperate with the slots (e.g., slots 614 of FIG. 6A-10) extending through the top reflector 202 to cool the top wall 132 of the chamber body 102 such that temperature range on the interior surface 176 of the top wall 132 may operate between about 10 degrees Celsius and about 65 degrees Celsius cooler than nominally during material layer deposition, or between about 30 degrees Celsius and about 55 degrees Celsius cooler, or even between about 35 degrees Celsius and about 50 degrees Celsius cooler. In certain examples the system may be configured such that the interior surface 176 of the top wall 132 may operate about 40 degrees Celsius cooler than nominally during material layer deposition. Temperature reductions within these ranges may, in some examples, limit risk of devitrification of the quartz forming the chamber body during relatively prolonged deposition operations, enabling the chamber body to be employed to deposit thick epitaxial layers onto substrates.

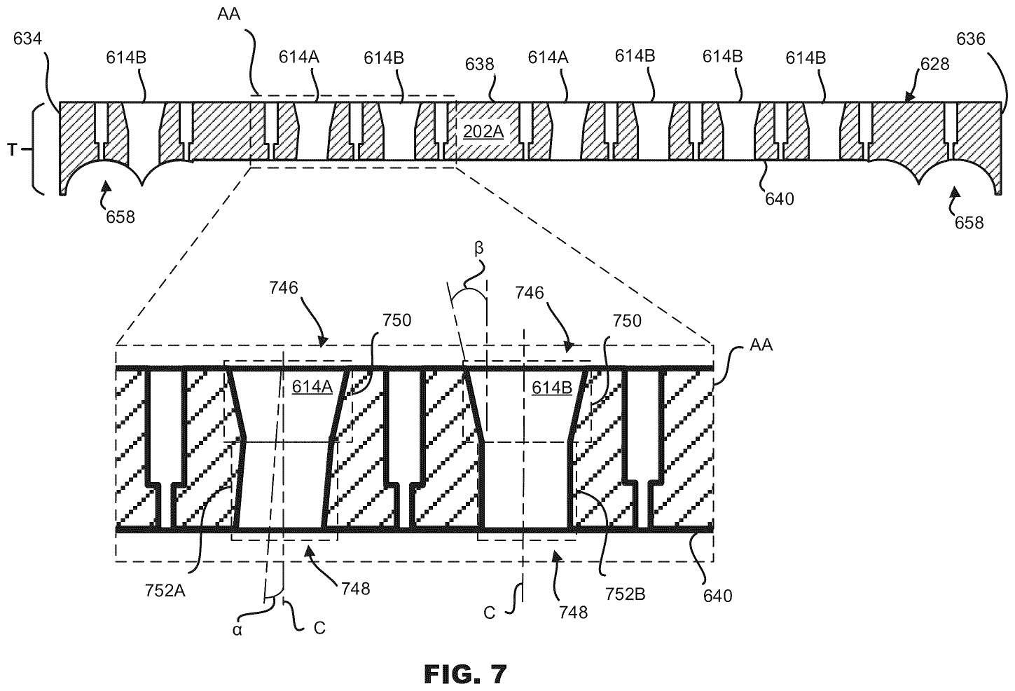

FIG. 6A depicts an example top reflector 202A (generally, top reflector 202). As described, the top reflector 202A may be configured to overlap the chamber body (e.g., chamber body 102 shown in FIG. 1). The top reflector 202A may comprise a reflector body 628. The reflector body 628 may comprise a first longitudinal side 630, a second longitudinal side 632 substantially opposed to the first longitudinal side. The reflector body 628 may further comprise a first lateral side 634, a second lateral side 636 substantially opposed to the first lateral side 634. The reflector body 628 may further comprise a grooved first surface 638, and a reflective surface 640 substantially opposed to the grooved surface. The grooved first surface 638 and the reflective surface 640 may be separated by a thickness (‘T’ in FIG. 7) of the reflector body 628. The first longitudinal side 630 and the second longitudinal side 632 may be located at longitudinally opposite ends of the reflector body 628, and may be spaced apart from one another by a longitudinal length of the reflector body 628. The first lateral side 634 and the second lateral side 636 may connect the first longitudinal side 630 and the second longitudinal side 632, and may be spaced apart from one another by a lateral width of the reflector body 628. If the reflector 202A is disposed in the semiconductor processing system 100, the first longitudinal side 630 may substantially overlay and/or be disposed proximate to the injection end (e.g., the injection end 126 shown in FIG. 1) of the chamber body (e.g., chamber body 102 shown in FIG. 1) and the second longitudinal side 632 may overlay and/or be disposed proximate to the exhaust end (e.g., exhaust end 128 shown in FIG. 1) of the chamber body 102. Additionally or alternatively, if the top reflector 202A is disposed in the semiconductor processing system 100, the heater element (e.g., heater element 108 shown in FIG. 1) may be disposed between the chamber body 102 and top reflector 202A. Additionally or alternatively, the heater element 108 may extend longitudinally between the first longitudinal side 630 and the second longitudinal side 632.

The grooved first surface 638 of the reflector body 628 may be longitudinally bounded by the first longitudinal side 630 and the second longitudinal side 632 of the reflector body 628, and laterally bounded by the first lateral side 634 and the second lateral side 636. The top reflector 202A may further comprise one or more pyrometer ports 642 extending therethrough. The pyrometer ports 642 may extends through a thickness (‘T’ in FIG. 7) of the reflector body 628. The pyrometer ports 642 may be configured to couple (e.g., optically couple) and/or engage a pyrometer (e.g., pyrometer 158, 160 shown in FIG. 1) to the chamber body (e.g., chamber body 102 shown in FIG. 1). Optical coupling of the pyrometer may allow and/or enable the pyrometer to detect, record, and/or report information indicating a temperature reading from within the chamber body 102, (e.g., substrate support 118 shown in FIG. 1), and/or the substrate (e.g., substrate 180 shown in FIG. 1) supported on the substrate support 118. The reported temperature may be employed to control temperature within the chamber body 102 and/or of the walls of the chamber body 102, for example, during deposition of the material layer (e.g., material layer 182 shown in FIG. 1) onto the substrate 180. The pyrometer ports 642 may be longitudinally and/or laterally offset from each other. Example top reflectors 202 having one or more second pyrometer ports may allow for monitoring temperature of the chamber body 102 at one or more second locations. Such temperature monitoring at a second location may improve the ability to control and/or maintain temperature of the substrate (e.g., substrate 180 shown in FIG. 1) and the chamber body 102 during deposition of the material layer (e.g., material layer 182 shown in FIG. 1) onto the substrate 180. Although shown as having two (2) pyrometer ports, it is to be understood and appreciated that examples of the reflector body 628 may have fewer (e.g., 1) or more (e.g., 3, 4, 5, etc.) pyrometer ports.

As described, the top reflector 202A may comprise a grooved first surface 638 defining therein a plurality of expansion grooves 644. The plurality of expansion grooves 644 may be defined within the grooved first surface 638 of the reflector body 628 laterally or longitudinally, and may extend toward the second surface 207 (shown in FIG. 1) of the reflector body 203 and partially through the thickness 213 (shown in FIG. 3) of the reflector body 203. The expansion grooves 644 may be configured to limit deformation of the reflector body 628 due to heating. A first portion of the plurality of expansion grooves 644 may separate the pyrometer port 642 from the first lateral side 634 and the second lateral side 636. The plurality of expansion grooves may be about evenly spaced from one another between the first lateral side 634 and the second lateral side 636 of the reflector body 628, and may extend between the first longitudinal side 630 and the second longitudinal side 632 of the reflector body 628. The plurality of expansion grooves 644 may extend in parallel with one another. The plurality of expansion grooves 644 may be substantially orthogonal in relation to either (or both) of the first longitudinal side 630 and the second longitudinal side 632. It is also contemplated that, in accordance with certain example configurations, the plurality of expansion grooves 644 may be substantially parallel to either (or both) the first lateral side 634 and the second lateral side 636. Although shown as having ten (10) expansion grooves 644, it is to be understood and appreciated that examples of the reflector body 628 may have fewer (e.g., 9, 8, 7, 2, etc.) or more (e.g., 11, 12, 13, 20, etc.) expansion grooves 644.

FIG. 6B depicts the reflective surface 640 side of the example top reflector 202A of FIG. 6A. Referring to FIG. 6B, the reflective surface may comprise a reflective layer 654. The reflective layer 654, may comprise a material of relatively increased reflectivity, for example, gold. The reflective layer 654 may be configured to reflect electromagnetic radiation, for example, emitted by heater elements (e.g., heater element 108 of FIG. 1 and/or heater element array 874 of FIG. 8) toward a below situated chamber body (e.g., chamber body 102 of FIG. 1). Accordingly, the top reflector may increase the amount of heat a heater element (e.g., heater element 108 of FIG. 1) may communicate to the chamber body per unit of power applied to the heater element. The top reflector 202A may further comprise an intermediate layer 656. The intermediate layer 656 may be configured to couple the reflective layer 656 to the reflector body 628. Examples of intermediate layers 656 may include coatings including, for example, nickel and nickel-containing material. Use of an intermediate layer 656 may accommodate for mismatch between thermal expansion of the reflector body 628 material and the reflective layer 654 material.

The top reflector 202A (e.g., reflector body 628) may comprise one or more slots 614 (e.g., angled slots 614A and substantially straight slots 614B; generally, slots 614) (e.g., channels). Each of the slots 614 may extend through the thickness of the reflector body 628. For example, each slot 614 may comprise an aperture through the thickness of the reflector body 628. Additionally or alternatively, each of the slots 614 may comprise a channel through the reflector body 628 (e.g., through a thickness of the reflector body 628). Additionally or alternatively, each of the slots 614 may comprise an elongated through hole in the reflector body 628 (e.g., through a thickness of the reflector body 628). Each of the plurality of slots 614 may extend lengthwise between the first longitudinal side 630 and the second longitudinal side 632 of the reflector body 628. Additionally or alternatively, a plurality of slots 614 may be disposed and/or distributed laterally between the first lateral side 634 and the second lateral side 636 of the reflector body 628.

FIG. 7 depicts a cross-sectional view of the example top reflector 202A of FIGS. 6A and 6B. FIG. 7 further depicts magnified section AA. Referring to FIG. 7, as described, the slots 614 may comprise through-holes in the reflector body 628. For example, the reflector body 628 may comprise one or more first surface apertures 746 (e.g., opening), for example, in the grooved first surface 638. Additionally, the reflector body 628 may comprise one or more second surface apertures 748 (e.g., openings) in a second surface, for example, in the reflective surface 640. Each slot 614 may comprise a channel fluidly coupled between the first surface aperture 746 and the second surface aperture 748. For example, as described, coolant may be issued (e.g., flowed) from the grooved first surface 638 through the slots 614 to the reflective surface 640. Additionally or alternatively, coolant may be issued from the first surface aperture 746, through the slot 614, and through the second surface aperture 748. Accordingly, if the top reflector 202A is positioned above the chamber body (e.g., chamber body 102 of FIG. 1), coolant may be directed, via the slots 614, onto and exterior surface of the top wall (e.g., top wall 132 of FIG. 1) of the chamber body to cool the top wall and/or the chamber body. Accordingly, the configuration (e.g., shape, direction, etc.) of the slots 614 may affect the cooling efficiency, consistency, and/or uniformity of the chamber body employed in the chamber arrangement included in the semiconductor processing system.

With continued reference to FIG. 7, as described, the slots 614 may be configured to affect the flow of coolant therethrough. For example, in some example configurations, the first surface aperture 746 may be larger than the second surface aperture 748. Additionally or alternatively, one or more of the slots 614 may narrow between the first surface aperture 746 and the second surface aperture 748. Additionally or alternatively, the slots 614 may comprise internal channels (e.g., comprising walls) extending between the first surface aperture 746 and the second surface aperture 748. Additionally or alternatively, the slots 614 (e.g., channels) may comprise a cross-sectional profile. The cross-sectional profile of each of the slots 614 may comprise one or more shapes. For example, each of the slots 614 may comprise a first portion 750, for example, extending from the first surface aperture 746 and a second portion 752 (e.g., angled second portion 752A and substantially vertical second portion 752B in FIG. 7; generally, second portion 752) extending from the first portion 750. The first portion 750 and the second portion 752 may be differently configured and/or shaped. For example, the first portion 750 may comprise a substantially trapezoidal shaped cross-sectional profile. Additionally or alternatively, the walls of the first portion 750 may be inclined from the first surface aperture 746. For example, the walls of the first portion 750 may be inclined toward a center (e.g., toward centerline ‘C’ of FIG. 7) of the slot 614, for example, as the first portion 750 extends from the first surface aperture 746. The walls of the first portion 750 may narrow at an angle of incline ‘β’. In one or more example configurations, the angle of incline β may be about 15° from a surface normal (e.g., a surface normal vector) (e.g., defined by centerline ‘C’). In one or more other example configurations, the angle of incline β may be in a range from about 5° to about 25°.

With continued reference to FIG. 7, as described herein, the slots 614 may be configured to issue, direct, and/or deliver coolant (e.g., to an external surface of a top wall of a chamber body). One or more of the slots 614 (e.g., angled slots 614A) may be configured to issue coolant, flowing through the slots 614 from the grooved first surface 638, at a flow angle oblique relative to the reflective surface 640 of the reflector body. For example, in one or more example configurations, the second surface aperture 748 may be closer to the first lateral side 634 than the first surface aperture 746. Additionally or alternatively, the second surface aperture 748 may be closer to the second lateral side 636 than the first surface aperture 746. Additionally or alternatively, as described, the slots 614 may comprise a channel. Additionally, the angled slots 614A may comprise a first portion 750 (e.g., first region) and an angled second portion 752A (e.g., second region). The angled second portion 752A may extend from the first portion 750. The angled second portion 752A may terminate at the second surface aperture 748. The angled second portion 752A may comprise a cross-sectional profile. The profile of the cross-section of the angled second portion 752A may substantially comprise a parallelogram shape. For example, the profile of the cross-section of the angled second portion 752A may substantially comprise a rhombus shape. In one or more example configurations, the angled second portion 752A, (e.g., the walls of the angled second portion 752A) may extend at an oblique angle ‘α’ to a surface normal (e.g., a surface normal vector) (e.g., defined by centerline ‘C’) to the slot 614. Additionally or alternatively, the angled second portion 752A (e.g., of the channel) may extend at an oblique angle α relative to a substrate (e.g., substrate 180 of FIG. 1) seating plane, for example, defined by a substrate support (e.g., substrate support 118 of FIG. 1). In some example configurations, the angle α may be about 5°measured relative to a surface normal (e.g., centerline ‘C’). In one or more additional or alternative configurations, the angle α may range from about 3° to about 8° measured relative to a surface normal. The angled second portion 752A may extend (e.g., from the first portion 750) toward the reflective surface 640 at an incline and/or angle toward the first lateral side 634 or the second lateral side 636. In such regards, one or more of the angled slots 614A may be configured to issue coolant, flowing through the slots 614 from the grooved first surface 638 to the reflective surface 640, at a flow angle oblique relative to the reflective surface 640.

In one or more example configurations, the slots 614 may be alternatively configured. For example, with continued reference to FIG. 7, one or more of the slots 614 (e.g., substantially vertical slots 614B) may comprise a substantially vertical second portion 752B. For example, the cross-sectional profile of the substantially vertical second portion 752B may be substantially square and/or rectangular. For example, the substantially vertical second portion 752B may extend substantially vertically from the first portion 750. Additionally or alternatively, the substantially vertical second portion 752B may extend substantially vertically between the first portion 750 and the second surface opening 748.

As described, the top reflector 202A may comprise a plurality of slots 614. The example configuration of FIG. 7 depicts 7 slots 614. Other example configurations may comprise more (e.g., 8, 9, 10, 11, etc.) or fewer (e.g., 6, 5, 4, etc.) slots 614. Some of the plurality of slots 614 or all of the plurality of slots 614 may be angled slots 614A. Additionally or alternatively, all of the plurality of angled slots 614A may be angled toward the same side (e.g., toward first lateral side 634 or second lateral side 636). Alternatively, a first portion of the angled slots 614A may be angled toward a first side (e.g., first lateral side 634), and a second portion of the angled slots 614A may be angled toward a second (e.g., opposing) side (e.g., second lateral side 636). In example configurations that include both angled slots 614A and substantially vertical slots 614B, the differently configured slots may be variously distributed on the top reflector 202A.

The reflective surface 640 may comprise a plurality of concave surface portions 658. The plurality of concave surface portions 658 may extend between the first longitudinal side 630 (e.g., shown in FIGS. 6A and 6B) and the second longitudinal side 632 (e.g., shown in FIGS. 6A and 6B) of the reflector body 628. The plurality of concave surface portions 658 may define a concave profile between the first lateral side 634 and the second lateral side 636 of the reflector body 628, and a portion of the plurality of slots may be defined in the concave surface portions 658. The plurality of concave surface portions 658 may extend in parallel with one another between the first longitudinal side 630 and the second longitudinal side 632 of the reflector body 628. Additionally or alternatively, the plurality of concave surface portions 658 may be substantially orthogonal to either (or both) of the first longitudinal side 630 and the second longitudinal side 632. It is also contemplated that plurality of concave surface portions 658 may extend in parallel with either (or both) the first lateral side 634 and the second lateral side 636.

FIG. 8 depicts an example top reflector 202A disposed above a heater array 874 and top wall 132 of a chamber body 102. As described, in used, the top reflector 202A may be disposed and/or arranged above a top wall 132 of a chamber body 102. A heater element and/or heater element array may be disposed between the top reflector 202A and the top wall 132 of the chamber body. Additionally as described, in use, the top reflector 202A may be used to direct and/or flow coolant (e.g., coolant 384 of FIG. 3) over the top wall 132 of chamber body 102. As described herein and as depicted in FIG. 8, the top wall 132 of the chamber body 102 may comprise a plurality of ribs 154. For example, the top wall 132 may comprise a plurality of ribs 154 extending from an exterior surface. The ribs 154 may provide structural support to the chamber body 102 and/or allow the interior 130 of the chamber body 102 to be maintained at relatively low pressure relative to the environment outside of the chamber body 102. It may be appreciated that the ribs 154 may disrupt and/or disturb the flow of coolant, if flowed over the top wall 132. Additionally or alternatively, the ribs 154 may cause the coolant to stagnate in one or more regions, for example, between two neighboring ribs 154. The presence of the ribs 154 may tend to affect cooling performance and/or efficiency. Accordingly, the slots 614 of the present disclosure may be used to improve the cooling efficiency in such configurations. For example, angled slots 614A may be variously arranged and distributed in top reflector 202A to direct coolant at an angle that is oblique to the reflective surface 640 and/or oblique to the top wall 132 of the chamber body 102. The slots 614, for example, angled slots 614A and substantially vertical slots 614B may be distributed in the top reflector to increase the recirculation zones and decrease a temperature boundary layer, for example, between two ribs 154. In this manner, the cooling efficiency of the top reflector 202A and/or the system may be improved.

Referring back to FIGS. 6A and 6B, as described, the top reflector 202A may comprise a plurality of slots 614. The plurality of slots 614 may comprise slots of different lengths. For example, different slots 614 may extend different lengths and/or distances between the first longitudinal side 630 and the second longitudinal side 632 of the reflector body 628. FIGS. 6A and 6B depict a single example configuration comprising six (6) elongated slots and one (1) shortened slot. Additionally, FIGS. 6A and 6B depict a particular example lateral distribution of the slots 614. In other example configurations, the slots 614 may be configured and/or distributed differently.

FIG. 9 depicts an alternative example top reflector 202B. reflector 202B of FIG. 9 may be substantially similar to reflector 202, reflector 202A, and reflector 202C of FIGS. 1, 2, 3, 4, 6A, 6B, 7, 8, 10 unless as otherwise explicitly described herein. Referring to FIG. 9, the top reflector 202B may include four (4) elongated slots 614 and ten (10) shortened slots. Additionally, in the example configuration of FIG. 9, the top reflector 202B the slots 614 may be distributed substantially as depicted. Additionally, the plurality of slots 614 may be disposed in multiple groups, a first group may include relatively elongated slots 614 and a second group may comprise relatively shortened slots 614. Slots 614 of the two groups may be variously distributed across the reflector body 628. Additionally or alternatively, example reflector bodies 628 may include more (e.g., three (3) groups, four (4) groups, etc.) or less differently sized slots 614. Additionally, FIG. 9 depicts an example top reflector having 2 pyrometer ports 642. Other example configurations may include more or fewer pyrometer ports 642.

FIG. 10 depicts an alternative example top reflector 202C. Reflector 202C of FIG. 10 may be substantially similar to reflectors 202, reflector 202A, and reflector 202B of FIGS. 1, 2, 3, 4, 6A, 6B, 7, 8, and 9, unless as otherwise explicitly described herein. Referring to FIG. 10, the top reflector 202B may include one or more relatively shortened slots 614, one or more relatively intermediate length slots 614, and one or more relatively elongated slots. Additionally, in the example configuration of FIG. 10 of the top reflector 202C, the slots 614 may be distributed substantially as depicted. Additionally, the plurality of slots 614 may be disposed in multiple groups, a first group may include one or more (e.g., three (3)) relatively elongated slots 614, a second group may comprise one or more relatively intermediate length slots 614, and a third group may include one or more (e.g., two (2)) relatively shortened slots 614. Slots 614 of the three groups may be variously distributed across the reflector body 628. Additionally or alternatively, example reflector bodies 628 may include more (e.g., four (4) groups, five (5), etc.) or less differently sized slots 614. Additionally, FIG. 10 depicts an example top reflector 202C having 2 pyrometer ports 642. Other example configurations may include more or fewer pyrometer ports 642.

In accordance with further embodiments of the disclosure, a reflector configuration is provided that may differ in certain aspects from both solid and slotted reflectors. In some embodiments, the reflector is reconfigurable and includes selectively blocked slots, wherein quartz rods may be inserted into one or more slots to modulate airflow through the reflector. In such embodiments, by adjusting the number and position of quartz rods, the chamber temperature may be tuned to a target range suitable for all further processes, for example, where chamber temperature between 550° C. and 600° C. may be desirable. Such a reconfigurable configuration may enable sustainable coating-free operation, which may extend tool performance.

In one embodiment, the reflector comprises a body having a plurality of slots extending through its thickness, as illustrated in FIG. 8 and FIG. 9. Quartz rods 804 are removably inserted into selected slots, acting as airflow blockers, as illustrated by call-out region 806 of FIG. 8 where exemplary quartz rod 804 is inserted into slot 614B. The number, length, and arrangement of quartz rods 804 can be varied to control the distribution and rate of coolant flow (as illustrated by air flow 802 of FIG. 8) through the reflector, thereby tuning the chamber temperature. The air flow 802 is directed through the slots, with the quartz rods 804 selectively blocking or allowing passage to achieve the desired cooling effect. In various embodiments, experimental results demonstrate that, with appropriate quartz rod arrangements, chamber temperature can be maintained within the desired range without triggering blower over-temperature alarms, and chamber coating can be significantly reduced or eliminated even under high-temperature process conditions. In use, the quartz rods 804 may be manually or automatically inserted into or removed from the slots (e.g., 614A and 614B) of the reflector body prior to or during a deposition process. The selection of which slots to block, and the number and arrangement of quartz rods 804, may be determined based on the desired chamber temperature profile for a specific process recipe. The rods may be sized to fit securely within the slots, and may be color-coded or marked for easy identification and adjustment. This adjustability allows for rapid tuning of chamber conditions without requiring replacement of the entire reflector.

In certain embodiments employing the quartz rods, the reflector may be formed as a single piece with only the necessary slots for process control, omitting unused slots to further optimize airflow and temperature distribution. In such embodiments, pyrometer ports may be provided to enable real-time temperature monitoring at multiple locations within the chamber, facilitating closed-loop temperature control. In some embodiments, the reflector is integrated into a chamber cooling system that includes a blower for circulating coolant across the exterior of the chamber body. Coolant may be directed through the slots in the reflector, with the flow pattern and rate controlled by the presence or absence of quartz rods. The system may operate in either open-loop or closed-loop mode, with temperature feedback provided by pyrometers to adjust blower speed or rod arrangement as needed for optimal process control. In certain examples, the adjustable reflector configuration may be suitable for a variety of semiconductor deposition processes, including deep-trench etching, epitaxial growth, and high-temperature chemical vapor deposition. The system may be used with different substrate sizes and materials, and the reflector design may be customized for specific chamber geometries or process requirements. The ability to tune chamber temperature and airflow enables improved uniformity, reduced defect rates, and extended chamber maintenance intervals. In addition, the quartz rods and reflector bodies may be designed for durability and ease of maintenance. For example, the quartz rods may be replaced individually if damaged or contaminated, and the reflector body may be cleaned or refurbished as needed. As such, the module and reconfigured able design allows for quick reconfiguration to accommodate new process recipes or chamber upgrades.

In addition, in certain embodiments, the reflector body may be formed from a copper-containing material, such as brass or bronze, to provide high thermal conductivity and mechanical stability during semiconductor processing. In such embodiments, the reflective surface of the reflector may include a layer of gold deposited onto the copper-containing body to enhance reflectivity and thermal performance. In some configurations, an intermediate layer, such as nickel, may be provided between the copper-containing body and the gold layer to accommodate differences in thermal expansion and improve adhesion. While copper-containing materials and gold reflective layers may be employed, alternative materials such as aluminum alloys, silver, or other high-reflectivity coatings may be used for the reflector body and surface, provided they offer suitable thermal and mechanical properties.

In some embodiments, the quartz rods 804 used as airflow blockers may be manufactured from high-purity quartz, selected for its durability and resistance to the high temperatures encountered during deposition processes. Similarly, alternative rod materials, other than quartz, may be considered for specific process environments. For example, in certain embodiments, the airflow-blocking rods may be formed from materials other than quartz, provided they offer suitable thermal stability, chemical resistance, and mechanical strength for semiconductor processing environments. Alternative materials may include alumina (Al₂O₃), silicon carbide (SiC), sapphire, fused silica, boron nitride (BN), zirconia, silicon nitride (Si₃N₄), or metal alloys with protective ceramic coatings. Selection of rod material may be based on the specific temperature, chemical exposure, and durability requirements of the deposition process.

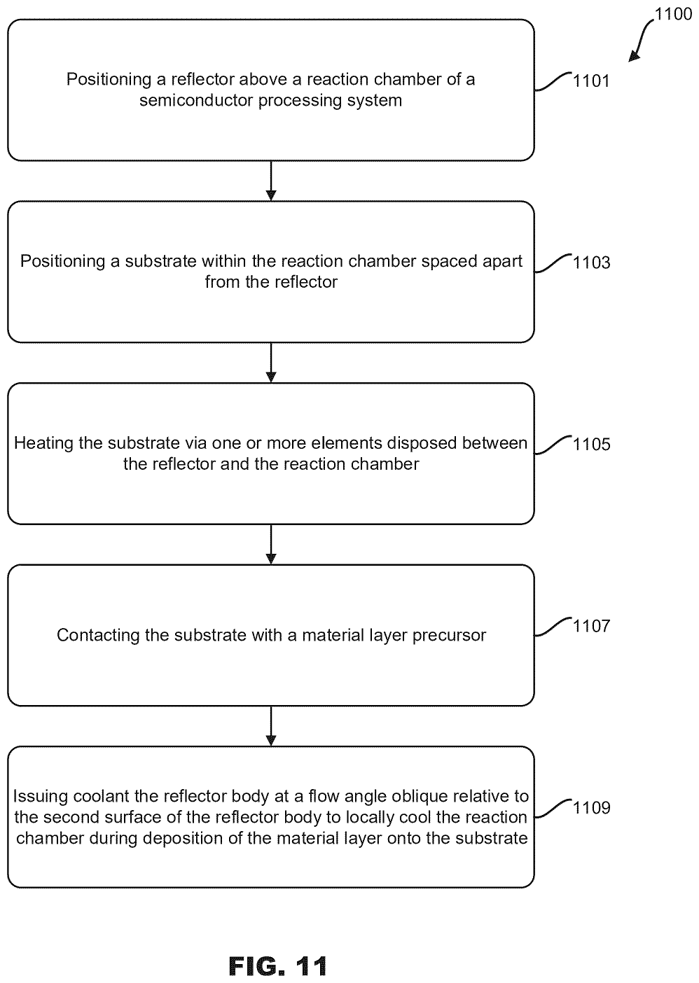

FIG. 11 shows an example method 1100 associated with reflectors herein (e.g., top reflectors 202A of FIGS. 6A-8, top reflector 202B of FIG. 9, and top reflector 202C of FIG. 10; generally, reflector 202). One or more steps of example method 1100 may be omitted and/or reordered without deviating from the scope of this disclosure. At step 1101, the reflector (e.g., top reflector 202A of FIGS. 6A-8, top reflector 202B of FIG. 9, or top reflector 202C of FIG. 10) may be disposed (e.g., positioned) above a chamber body (e.g., chamber body 102 of FIG. 1) of a semiconductor processing system (e.g., semiconductor processing system 100 of FIG. 1). Disposing the reflector above the chamber body may comprise overlapping the reflector with a portion of the chamber body, for example, a top wall of the chamber body (e.g., top wall 132 of FIG. 1). Additionally or alternatively, disposing the reflector above the chamber body may comprise disposing the reflector above one or more heater elements (e.g., heater element 108 and/or heater element array 874 of FIG. 8). The reflector may be spaced apart from the chamber body.

At step 1103, a substrate (e.g., substrate 180 of FIG. 1) may be disposed (e.g., positioned and/or seated) within the chamber body of the chamber arrangement chamber. Disposing the substrate in the chamber body may comprise disposing (e.g., positioning and/or seating) the substrate on a substrate support (e.g., substrate support 118 of FIG. 1).

At step 1105, the substrate may be heated. The substrate may be heated, for example, via one or more heater elements (e.g., heater element 108 of FIG. 1 and/or heater element array 874 of FIG. 8). The heater elements may be disposed between the reflector and the chamber body. For example, the one or more heater elements may be positioned in electromagnetic radiative communication with the top wall of the chamber body. Additionally or alternatively, the one or more heater elements may be positioned in electromagnetic radiative communication with the above disposed top reflector. The electromagnetic radiation may be reflected from the one or more heater elements in direction substantially opposite the substrate. The top reflector may be positioned to reflect, for example, via reflective surface (e.g., reflective surface 640 of FIGS. 6A-10) toward the top wall of the chamber body, a portion of the electromagnetic radiation received from the one or more heater elements.

At step 1107, the substrate may be contacted with a material layer precursor (e.g., substantially as described regarding a first precursor source 110 and one or more second precursor source(s) 112 of FIG. 1).

At step 1109, coolant (e.g., coolant 384 of FIG. 3) may be issued (e.g., flowed, directed) from the reflector to cool the chamber body during deposition of the material layer onto the substrate. For example, the coolant may be issued through the reflector, for example, through a reflector body (e.g., reflector body 628 of FIGS. 6A-10). For example, coolant may be introduced to and/or issued from a first surface of the reflector. For example, coolant may be introduced to one or more first surface apertures of the reflector. The coolant may be issued from a second surface of the reflector (e.g., reflective surface 640 of FIGS. 6A-10), for example, from one or more second surface apertures at a flow angle that is oblique relative to the second surface of the reflector body. The chamber body, and/or one or more portions thereof (e.g., a portion of the top wall) may be cooled (e.g., locally cooled), for example, during deposition of a material layer onto the substrate, via the coolant issued from the reflector.

Although examples are described above, features and/or steps of those examples may be combined, divided, omitted, rearranged, revised, and/or augmented in any desired manner. Various alterations, modifications, and improvements will readily occur to those skilled in the art. Such alterations, modifications, and improvements are intended to be part of this description, though not expressly stated herein, and are intended to be within the spirit and scope of the disclosure. Accordingly, the foregoing description is by way of example only, and is not limiting.

1. A reflector, comprising:
a reflector body having:
a first surface bounded in part by a side of the reflector body and defining therein a first surface aperture; and
a second surface also bounded in part by the side of the reflector body and including a reflective material, the second surface separated from the first surface by a thickness of the reflector body, the second surface defining therein a second surface aperture,
wherein the second surface aperture is fluidly coupled to the first surface aperture by a channel extending through the thickness of the reflector body,
wherein one of the first surface aperture and the second surface aperture is disposed closer to the side of the reflector than the other of the first surface aperture and the second surface aperture, and
wherein at least a portion of the channel is angled relative to at least one of the first surface and the second surface to issue a coolant from the second surface aperture at a flow angle oblique relative to the reflector body.

2. The reflector of claim 1, wherein the first surface of the reflector body defines therein a plurality of expansion grooves, the plurality of expansion grooves extending towards the second surface and partially through the thickness of the reflector body.

3. The reflector of claim 1, wherein the reflector body is formed from a copper-containing material, and wherein the reflective material includes gold.

4. The reflector of claim 1, wherein the reflector body defines therethrough a port, the port extending through the thickness of the reflector body, the port optically coupling the second surface of the reflector body along an optical axis substantially parallel to the side of the reflector body, wherein the channel is oblique relative to the optical axis.

5. The reflector of claim 1, wherein the reflector body further comprises a first longitudinal side and a second longitudinal side, wherein the first longitudinal side and the second longitudinal side are disposed substantially orthogonal to the side, and wherein the first surface aperture and second aperture extend in a direction between the first longitudinal side and second longitudinal side, the first surface aperture and the second surface aperture thereby cooperating with the channel to define an angled slot extending through the reflector body.

6. The reflector of claim 1, wherein a portion of the channel extends through a thickness of the reflector body at an angle relative to a surface normal.

7. The reflector of claim 1, wherein the first surface aperture and the second surface aperture define a slot within the reflector body, the slot having a major dimension and a minor dimension, the major dimension substantially parallel to the side of the reflector body.

8. The reflector of claim 1, wherein the reflector body is further configured to overlap a ribbed exterior surface of a wall of a chamber body of a semiconductor processing system, wherein the channel is configured to direct the coolant into a gap defined between adjacent ribs on the ribbed exterior surface of the wall of the chamber body.

9. The reflector of claim 1, wherein at least one slot extending through the reflector body is configured to receive a removable quartz rod, the quartz rod being operable to block airflow through the at least one slot.

10. The reflector of claim 9, wherein the number and arrangement of quartz rods inserted into the slots is adjustable to tune the temperature within a chamber during a deposition process.

11. The reflector of claim 1, further comprising one or more pyrometer ports extending through the reflector body, each one of the one or more pyrometer ports configured to optically couple a pyrometer to a chamber for temperature monitoring.

12. A chamber arrangement, comprising:
a reflector as recited in claim 1;
a chamber body spaced apart from the reflector;
a substrate support arranged within an interior of the chamber body and supported for rotation about a rotation axis; and
a heater element array arranged between the chamber body and the reflector, wherein the channel is oblique relative to a substrate seating plane defined by the substrate support.

13. The chamber arrangement of claim 12, wherein the reflector includes one or more removable quartz rods inserted into selected slots to control airflow and chamber body temperature.

14. The chamber arrangement of claim 12, wherein the chamber body temperature is maintained within a range of about 550° C. to about 600° C. during operation.

15. The chamber arrangement of claim 12, wherein the chamber body extends between an injection end and a longitudinally opposite exhaust end, wherein the chamber body has a plurality of ribs extending laterally about the chamber body and longitudinally spaced apart between the injection end and the exhaust end of the chamber body, and wherein the channel is oblique relative to the plurality of ribs.

16. The chamber arrangement of claim 12, wherein the substrate support comprises a susceptor structure configured to receive a semiconductor substrate, and wherein the heater element array is configured to direct electromagnetic radiation toward the chamber body.

17. The chamber arrangement of claim 12, wherein the reflector includes one or more removable quartz rods inserted into selected slots to control airflow and chamber body temperature.

18. A material layer deposition method, comprising:
at a chamber arrangement including a chamber body and a reflector spaced apart from the chamber body; the reflector including a reflector body having a first surface bounded in part by a side of the reflector body and defining therein a first surface aperture; a second surface also bounded in part by the side of the reflector body and including a reflective material, the second surface separated from the first surface by a thickness of the reflector body, the second surface defining there a second surface aperture, the second surface aperture fluidly coupled to the first surface aperture by a channel extending through the thickness of the reflector body, one of the first surface aperture and the second surface aperture is disposed closer to the side of the reflector than the other of the first surface aperture and the second surface aperture, and the channel angled relative to at least one of the first surface and the second surface,
seating a substrate within the chamber body;
heating the substrate using a heater element array disposed between the reflector and the chamber body at least in part using electromagnetic radiation emitted by the heater element array in a direction substantially opposite the substrate and reflected by the second surface of the reflector body;
contacting the substrate with a material layer precursor such that a material layer deposits onto the substrate; and
issuing a coolant from the second surface aperture at a flow angle oblique relative to the reflector body, whereby the chamber body is locally cooled during deposition of the material layer onto the substrate by the coolant issued from the second surface aperture.

19. The method of claim 18, further comprising adjusting the number and arrangement of quartz rods inserted into slots of the reflector to tune the chamber body temperature during deposition processes.

20. The method of claim 18, wherein issuing the coolant further comprises causing cooling of a portion of an interior of the chamber body during deposition of the material layer onto the substrate.
